(19) United States
(12) Patent Application Publication
(10) Pub. No.: US 2020/0083079 A1
(43) Pub. Date: Mar. 12, 2020

(54) VACUUM TRANSFER MODULE AND VACUUM TRANSFER METHOD

(71) Applicant: TOKYO ELECTRON LIMITED, Tokyo (JP)

(72) Inventors: Kazuharu YOKOUCHI, Nirasaki City (JP); Seiji ISHIBASHI, Nirasaki City (JP)

(21) Appl. No.: 16/564,504

(22) Filed: Sep. 9, 2019

(30) Foreign Application Priority Data
Sep. 12, 2018 (JP) 2018-170162

(51) Int. Cl. H01L 21/673; H01L 21/677

(52) U.S. Cl. CPC H01L 21/67393; H01L 21/67706

(57) ABSTRACT

A vacuum transfer module includes: a housing kept in a vacuum atmosphere and to which a load-lock module and a processing module for performing a vacuum process on a workpiece are connected; a transfer mechanism including a rotation body for rotating around a rotary shaft inside the housing, which transfers the workpiece between the load-lock module and the processing module through the interior of the housing; a gas supply port opened inside the housing to supply an inert gas for purging the housing; and an exhaust port opened inside the housing and through which the housing is exhausted to form the vacuum atmosphere when the inert gas is supplied, and formed such that an angle between a first straight line connecting the exhaust port and the rotary shaft, and a second straight line connecting the gas supply port and the rotary shaft ranges from 100 to 260 degrees.

### CROSS-REFERENCE TO RELATED APPLICATION

This application is based upon and claims the benefit of priority from Japanese Patent Application No. 2018-170162, filed on Sep. 12, 2018, the entire contents of which are incorporated herein by reference.

### TECHNICAL FIELD

The present disclosure relates to a vacuum transfer module and a vacuum transfer method.

### BACKGROUND

As an apparatus for manufacturing a semiconductor device, a multi-chamber type apparatus is known in which a plurality of processing modules is connected to a vacuum transfer chamber provided with a substrate transfer mechanism. Patent Document 1 discloses a configuration in which a purge gas is supplied from a gas supply port formed in the bottom portion of a vacuum transfer chamber and is exhausted from an exhaust port formed in the bottom portion of the vacuum transfer chamber.

### PRIOR ART DOCUMENT

### Patent Documents

Patent Document 1: Japanese Laid-Open Patent Publication No. 2003-17478

### SUMMARY

According to an embodiment of the present disclosure, there is provided a vacuum transfer module including: a housing whose interior is kept in a vacuum atmosphere, and to which a load-lock module and a processing module configured to perform a vacuum process on a workpiece are connected laterally from an outside of the housing; a transfer mechanism including a rotation body configured to rotate around a rotary shaft provided at a fixed position inside the housing, the transfer mechanism configured to transfer the workpiece between the load-lock module and the processing module through the interior of the housing kept in the vacuum atmosphere; a gas supply port opened inside the housing to supply an inert gas for purging the interior of the housing; and an exhaust port opened inside the housing and through which the interior of the housing is exhausted to form the vacuum atmosphere when the inert gas is supplied from the gas supply port, the exhaust port being formed such that an angle between a first straight line connecting the exhaust port and the rotary shaft; and a second straight line connecting the gas supply port and the rotary shaft falls within a range of 100 to 260 degrees in a plan view.

### BRIEF DESCRIPTION OF DRAWINGS

The accompanying drawings, which are incorporated in and constitute a portion of the specification, illustrate embodiments of the present disclosure, and together with the general description given above and the detailed description of the embodiments given below, serve to explain the principles of the present disclosure.

FIG. 1 is a plan view illustrating an embodiment of a vacuum processing apparatus provided with a vacuum transfer module of the present disclosure.

FIG. 2 is a plan view illustrating an embodiment of a vacuum transfer module of the present disclosure.

FIG. 3 is a schematic vertical cross-sectional view illustrating a portion of the vacuum transfer module.

FIG. 4 is a plan view illustrating another embodiment of the vacuum transfer module of the present disclosure.

FIG. 5 is a plan view illustrating a portion of the vacuum transfer module of the present disclosure.

FIG. 6 is a plan view illustrating an example of a conventional vacuum transfer module.

FIG. 7 is a characteristic diagram representing evaluation results of oxygen concentration in the vacuum transfer module.

FIG. 8 is a characteristic diagram representing evaluation results of oxygen concentration in the vacuum transfer module.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

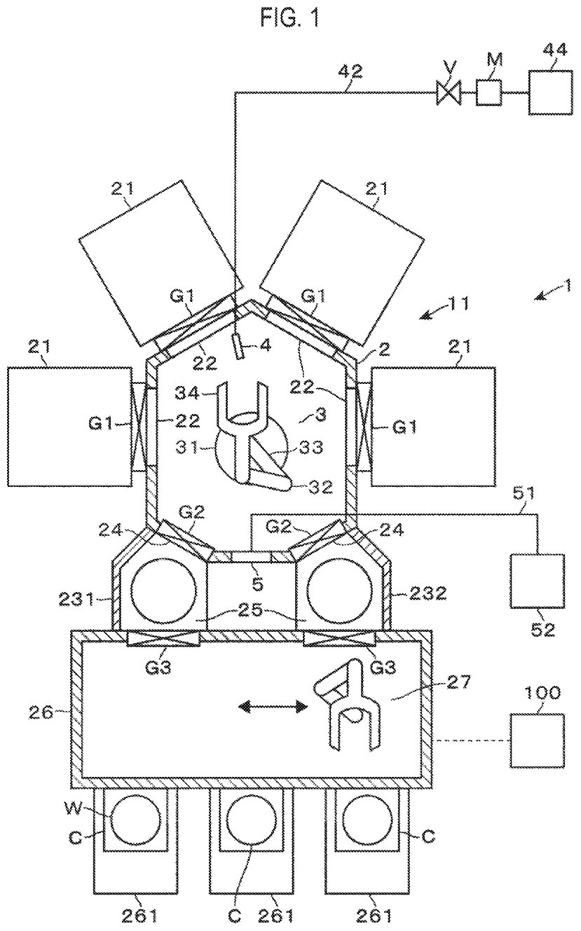

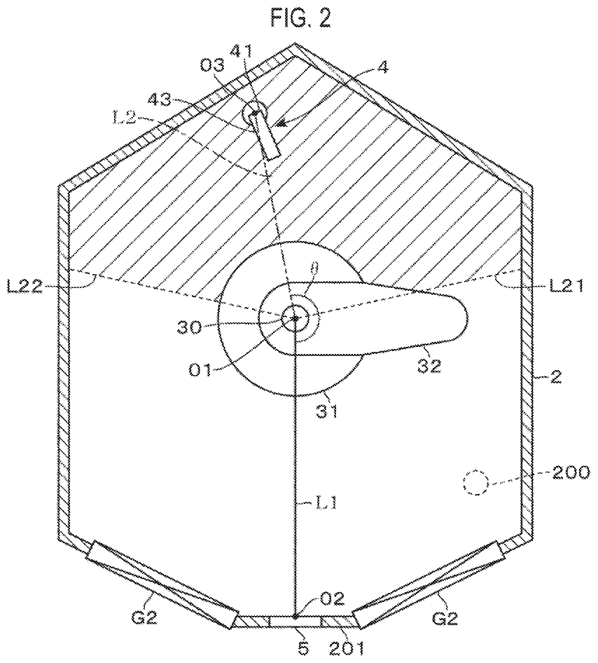

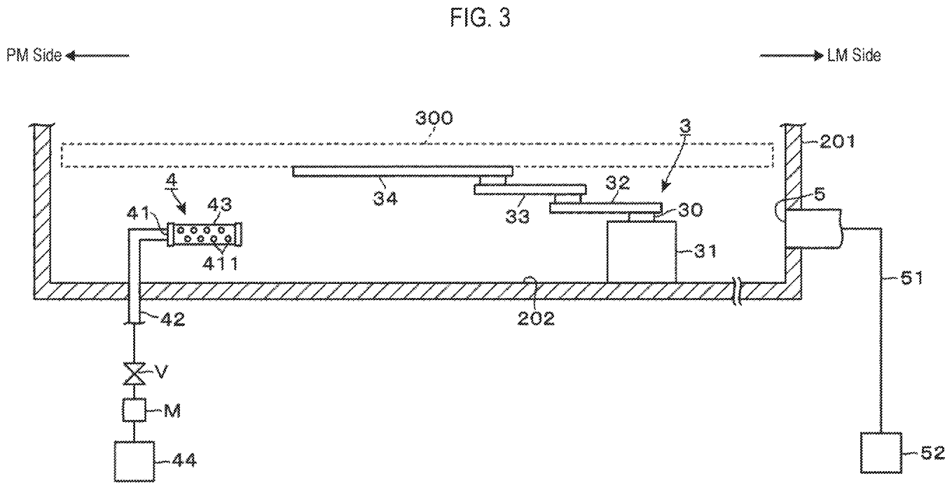

A first embodiment of a vacuum processing apparatus provided with a vacuum transfer module of the present disclosure will be described with reference to FIGS. 1 to 3. FIG. 1 is a plan view illustrating an example of a vacuum processing apparatus 1, FIG. 2 is a plan view illustrating an example of a vacuum transfer module 11, and FIG. 3 is a vertical cross-sectional view illustrating a portion of the vacuum transfer module 11. As illustrated in FIG. 1, the vacuum transfer module 11 includes a housing 2 whose interior is kept in a vacuum atmosphere, and formed in, for example, a substantially septangle shape in a plan view. For example, processing modules 21 are hermetically coupled to four sides of the septangle housing 2 along a lateral direction from the outside through respective transfer ports 22. Load-lock modules 231 and 232 are coupled to other two sides of the septangle housing 2 in the lateral direction from the outside through respective transfer ports 24. Reference symbols G1 and G2 in FIG. 1 denote gate valves.

Each processing module 21 is a module that performs a vacuum process on a workpiece such as a semiconductor wafer (hereinafter, referred to as a “wafer”) W, which is a circular substrate having a diameter of 300 mm. For example, a stage on which the wafer W is mounted, a gas supply part for supplying a processing gas, and a gas exhaust part for exhausting the processing gas are provided inside the processing module 21. Examples of the process implemented by the processing module 21 may include a film forming process performed using a film forming gas, an etching process performed using an etching gas, an ashing process performed using an aching gas, and the like. In addition, an example of the film forming process may include a process of heating the wafer W in a vacuum atmosphere to form, for example, a titanium nitride (TiN) film.

The load-lock modules 231 and 232 are configured such that the interior thereof is switched between a vacuum atmosphere and a normal pressure atmosphere. The load-lock modules 231 and 232 are coupled to a loader module 26 through respective transfer ports 25. Each of the transfer ports 25 is opened and closed by a gate valve G3. The loader module 26 is kept in a normal pressure atmosphere, and includes loading/unloading ports 261 on each of which a carrier C, which is a transfer container accommodating the wafers W, is mounted. In addition, the loader module 26 is provided with a normal-pressure transfer arm 27. The normal-pressure transfer arm 27 is configured to be swingable, extendible, and movable up and down to transfer the wafer W between the carrier C and each of the load-lock modules 231 and 232.

A transfer mechanism 3 is provided inside the housing 2 to transfer the wafer W between each of the load-lock modules 231 and 232 and the respective processing module 21. As illustrated in FIGS. 1 and 3, the transfer mechanism 3 may be configured as an articulated arm including a base 31, a first arm 32, a second arm 33, and a substrate support portion 34 which are connected in the above order from the lower side. The base 31 may be provided substantially in the central portion inside the housing 2. The transfer mechanism 3 may be configured to be liftable using a lifter.

The first arm 32 constitutes a rotation body, and is provided on the base 31 so as to rotate about a rotary shaft 30. In FIG. 2, only the base 31 and the first arm 32 are illustrated. In this example, the rotary shaft 30 is fixed at a horizontal position inside the housing 2 such that the rotational center of the rotary shaft 30 coincides with a substantially central portion of the housing 2. The rotary shaft 30 is configured to be rotatable about a vertical axis. The second arm 33 is rotatably provided on a tip end of the first arm 32. The substrate support portion 34 functions as a holding portion. A base end of the substrate support portion 34 is configured to be rotatable while being pivotably supported by a tip end of the second arm 33, and a tip end thereof is formed in a fork shape to hold the wafer W.

Each of the first arm 32 and the second arm 33 includes a driving force transmission system such as pulleys and belts, and is configured such that the substrate support portion 34 is rotatable and movable back and forth by, for example, a swing-purpose motor and a reciprocating-purpose motor (not illustrated). The wafer W is transferred while being held by the substrate support portion 34. Thus, as illustrated in FIG. 3, a transfer path 300 along which the wafer W is transferred corresponds to an area in which the substrate support portion 34 moves.

The vacuum transfer module 11 includes a gas supply part 4. For example, as illustrated in FIG. 3, the gas supply part 4 is configured by providing a filtering portion 43 made of, for example, a porous body made of ceramic, at a tip end of a gas supply path 42. The gas supply part 4 includes a gas supply port 41 opened inside the housing 2 to supply an inert gas for purging the interior of the housing 2. In this example, the tip end (downstream end) of the gas supply path 42 corresponds to the gas supply port 41. The gas supply path 42 is coupled to the filtering portion 43 via the gas supply port 41. Thus, the gas supply path 41 serves as a connection portion between the gas supply path 42 and the filtering portion 43. That is to say, it is assumed that the porous body (the filtering portion 43) is an atmosphere, and individual pores of the porous body do not correspond to a gas supply port cited in the accompanying claims. Therefore, in the present embodiment, the gas supply port cited in the accompanying claims corresponds to the above-described connection portion, namely a downstream end of the gas supply path 42 connected to the upstream side of the porous body.

The filtering portion 43 may be formed in a hollow cylindrical shape. For example, a “Break Filter” (commodity name) may be used as the filtering portion 43. As described above, when the gas supply part 4 is configured using the filtering portion 43 made of a porous body, each pore in the porous body is an ejection hole 411 for ejecting the gas. In FIG. 3, the ejection holes 411 are drawn on a large scale for the sake of convenience in illustration.

As illustrated in FIGS. 2 and 3, the filtering portion 43 is provided below the transfer path 300 along which the wafer W is transferred by the transfer mechanism 3 inside the housing 2 such that a cylindrical portion of the filtering portion 43 may extend to face a bottom surface of the housing 2. In FIG. 3, reference symbol “PM” indicates the processing module 21, and reference symbol “LM” indicates the loader module 26. Assuming that the side of the loader module 26 is referred to as a front side and the side of the vacuum transfer module 11 is referred to as a rear side, the filtering portion 43 is located at the rear side (upper side in FIG. 2) in the vicinity of the central portion (the base 31) in the left-right direction inside the housing 2 when viewed from the top. The upstream side of the gas supply path 42 in the gas supply part 4 is coupled to a supply source 44 of an inert gas such as a nitrogen (N₂) gas, which is provided outside the housing 2, through a valve V and a flow rate controller M.

The vacuum transfer module 11 includes an exhaust port 5 opened inside the housing 2. When the purge gas is supplied from the gas supply port 41, an internal atmosphere of the housing 2 is exhausted through the exhaust port 5 to form a vacuum atmosphere. As illustrated in FIGS. 1 to 3, when viewed from the top, the exhaust port 5 of this embodiment is formed in a sidewall 201 between the two load-lock modules 231 and 232 in the housing 2 and below the transfer path 300 along which the wafer W is transferred by the transfer mechanism 3.

In this embodiment, the exhaust port 5 is formed slightly above a bottom surface 202 in the sidewall 201 of the housing 2. An upper end of the exhaust port 5 is positioned below the above-described transfer path 300. The exhaust port 5 is coupled to an exhaust mechanism 52 via an exhaust path 51. The exhaust mechanism 52 is constituted by a vacuum pump or the like and is provided with a pressure regulator (not illustrated) or the like. In the vacuum transfer module 11, when the wafer W is transferred, the purge gas is supplied into the housing 2 and simultaneously, is exhausted by the exhaust mechanism 52 such that the interior of the housing 2 is controlled to be kept in a predetermined vacuum atmosphere.

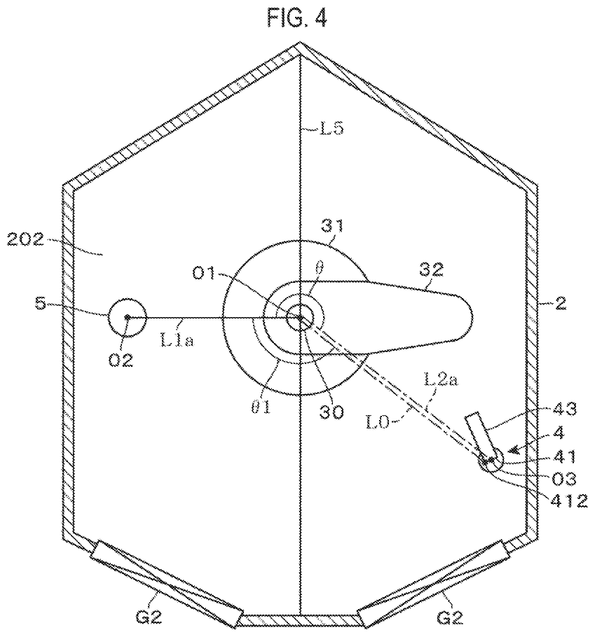

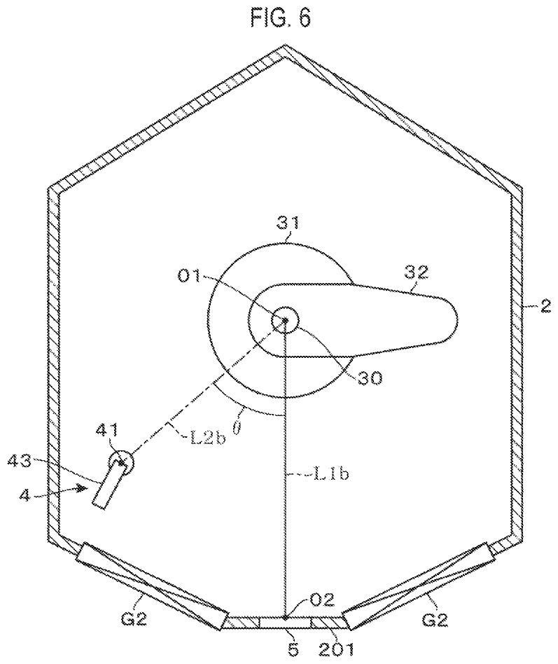

Next, a relative positional relationship between the gas supply port 41 at the tip end of the gas supply path 42 of the gas supply part 4 and the exhaust port 5 will be described. As illustrated in FIG. 2, it is assumed that in a plan view, a line connecting the rotary shaft 30 and the exhaust port 5 is a first straight line L1, and a line connecting the gas supply port 41 and the rotary shaft 30 is a second straight line L2. The gas supply port 41 is provided such that an angle θ between the first straight line L1 and the second straight line L2 falls within a range of 100 to 260 degrees. The numerical values of the angle θ are values set based on the results of an evaluation test in Examples and the like (to be described later). In FIG. 2, and FIGS. 4 and 6 described later, the gas supply part 4 is illustrated in a simplified manner for the sake of convenience in illustration, and the gas supply port 41 is illustrated to be positioned at the base end side of the filtering portion 43. In practice, the gas supply port 41 is positioned at the tip end of the gas supply path 42 as described above.

More specifically, as illustrated by the solid line in FIG. 2, the first straight line L1 is a straight line connecting a center O1 of the rotary shaft 30 and a center O2 of the exhaust port 5 (the center of the length in the lateral direction) in a plan view. The second straight line L2 is a straight line connecting the center O1 and a center O3 of the gas supply port 41 (the center of the length in the lateral direction), In FIG. 2, the second straight line L2 in the case where the angle θ=100 degrees is indicated as L21, and the second straight line L2 in the case where the angle θ=260 degrees is indicated as L22. That is to say, a hatched area S surrounded by straight lines L21 and L22 is an area in which the gas supply port 41 can be provided.

Specifically describing the second straight line L2, an end point of the straight line L2 is the center O3 of the gas supply port 41 in a plan view. If there are a plurality of gas supply ports 41, one located farthest from the exhaust port 5 when viewed in a direction in which the rotary shaft 30 rotates, corresponds to a gas supply port cited in the accompanying claims. More specifically, the gas supply port 41 disposed closest to the angle θ=180 degrees corresponds to a gas supply port cited in the accompanying claims. The reason for this is to reduce a concentration of oxygen inside the housing 2 (to be described later) by forming the gas supply port 41 at a position far away from the exhaust port 5. Accordingly, in the case where two gas supply ports 41 are formed, even if one is formed at the angle θ less than 100 degrees, the other may be formed at the angle θ ranging from 100 to 260 degrees.

In this embodiment, the gas supply port 41 is formed at a position where the angle θ is about 190 degrees. Since the angle θ is set in this manner, in the first embodiment, the gas supply port 41 and the exhaust port 5 are arranged such that the base 31 on which the rotary shaft 30 is provided is interposed between the gas supply port 41 and the exhaust port 5 in a plan view. Accordingly, the purge gas is supplied into all of the plurality of ejection holes 411 of the filtering portion 43 through the gas supply port 41.

As illustrated in FIG. 1, the vacuum processing apparatus 1 includes a controller 100 that controls the transfer operation of the wafer W, the processes such as the film forming processes performed in the processing modules 21, the switching operation of the atmosphere in the load-lock modules 231 and 232, and the like. The controller 100 is provided with a computer including, for example, a CPU and a storage part (both not illustrated). The storage part stores a recipe for the film forming process to be performed in the processing module 21 and a program including a group of steps (instructions) for transferring the wafers W by the transfer mechanism 3 and the normal-pressure transfer arm 27. This program may be stored in a storage medium such as a hard disk, a compact disk, a magneto-optical disk, a memory card or the like, and may be installed on the computer from the storage medium.

Next, the operation of the above-described vacuum processing apparatus 1 will be described. First, in the vacuum transfer module 11, the nitrogen gas as a purge gas is supplied from the plurality of ejection holes 411 of the filtering portion 43 through the gas supply port 41. Meanwhile, the purge gas is exhausted by the exhaust mechanism 52 through the exhaust port 5 so that a vacuum atmosphere having a regulated pressure is formed inside the housing 2. As described above, the gas supply port 41 and the exhaust port 5 are provided such that the angle between the first straight line L1 connecting the exhaust port 5 and the rotary shaft 30 and the second line L1 connecting the gas supply port 41 and the rotary shaft 30 falls within a range of 100 to 260 degrees. Accordingly, the gas supply port 41 and the exhaust port 5 are provided so as to face each other inside the housing 2 with the rotary shaft 30 interposed between the gas supply port 41 and the exhaust port 5.

With this configuration, a distance between the gas supply port. 41 and the exhaust port 5 is relatively long. Thus, the purge gas supplied from the plurality of ejection holes 411 of the filtering portion 43 through the gas supply port 41 sufficiently spreads throughout the interior of the housing 2 and is exhausted through the exhaust port 5. This replaces the internal atmosphere of the housing 2 by the purge gas. Thus, since the time oxygen stays inside the housing 2 is suppressed, it is possible to transfer the wafer W while maintaining the concentration of oxygen at a relatively low level. An internal pressure of the housing 2 during the wafer transfer may be 1.50 to 250 Pa, and the oxygen concentration may be 0.1 ppm or lower. Inside the housing 2, the supply of the purge gas from the gas supply port 41 and the exhaust of the purge gas from the exhaust port 5 are continuously performed until a series of processes on the wafer W are completed.

The wafers W accommodated in the carrier C on the loading/unloading port 261 are sequentially taken out by the normal-pressure transfer arm 27 and are transferred into the load-lock module 231 (or 232) kept in a normal pressure atmosphere. The interior of the load-lock module 231 (or 232) is switched to a vacuum atmosphere and subsequently, the wafer W is taken out by the transfer mechanism 3. The transfer mechanism 3 moves through the interior of the housing 2 to transfer the taken-out wafer W toward a respective processing module 21 and deliver on the stage of the respective processing module 21.

In the processing module 21, a film forming process of forming a TiN film is performed in the state in which the wafer W is heated to a predetermined temperature in a vacuum atmosphere of a predetermined pressure. When the process on the wafer W is completed in the processing module 21, the transfer mechanism 3 receives the wafer W from the processing module 21. The transfer mechanism 3 holding the processed wafer W moves through the interior of the housing 2 and delivers the processed wafer W to the load-lock module 231 (or 232) switched to the vacuum atmosphere. Subsequently, the load-lock module 231 (or 232) is switched into the normal pressure atmosphere, and then, the processed wafer W is returned to, for example, the original carrier C by the normal-pressure transfer arm 27.

According to the embodiment described above, since the positional relationship between the gas supply port 41 and the exhaust port 5 is set as described above, the purge gas sufficiently spreads throughout the interior of the housing 2 to suppress the staying of oxygen, thus reducing the oxygen concentration. As a result, when the wafer W subjected to the film forming process in the processing module 21 is transferred to the load-lock module 231 (or 232) through the interior of the housing 2, the oxidation of the thin film is suppressed, which makes it possible to maintain a sheet resistance value at a low level.

The gas supply port 41, the plurality of ejection holes 411 formed in the filtering portion 43, and the exhaust port 5 are provided below the transfer path 300 for the wafer W inside the housing 2. In this configuration, the purge gas is supplied downward of the wafer W which is being transferred by the transfer mechanism 3, and flows through the interior of the housing 2 toward the exhaust port 5. This makes it possible to prevent the position of the wafer W, which is being transferred, from being deviated by being exposed to a gas flow flowing from the gas supply port 41 toward the exhaust port 5 through the plurality of ejection holes 411 of the filtering portion 43. In addition, since the interior of the housing 2 is replaced with the purge gas which is not provided from above the wafer W, it is possible to suppress the contamination of the wafer W due to particles. However, the gas supply port 41, the filtering portion 43, and the exhaust port 5 are not limited to be arranged in the aforementioned manner. In some embodiments, the gas supply port 41 located at the tip end of the gas supply path 42 may be formed in a ceiling surface, the bottom surface 202, and the sidewall 201 of the housing 2.

Next, a second embodiment of the present disclosure will be described with reference to FIG. 4. In the second embodiment, the exhaust port 5 is formed in the bottom surface 202 of the housing 2. Assuming that the side of the loader module 26 is a front side (the lower side in FIG. 4) and the side of the processing module 21 is a rear side (the upper side in FIG. 4) in a plan view, the exhaust port 5 is provided at the left side in a left-right direction perpendicular to a straight line L5 set at the center of the housing 2 in the front-rear direction. In addition, the gas supply port 41 of the gas supply part 4 is provided close to the front side at the right side of the base 31 of the transfer mechanism 3 (the lower right side in FIG. 4). In this embodiment, the filtering portion 43 is provided such that the tip end thereof extends toward the central portion in the left-right direction at the rear side of the housing 2.

Even in the second embodiment, an angle θ between a first straight line L1a connecting the exhaust port 5 and the rotary shaft 30 and a second straight line L2a connecting the gas supply port 41 and the rotary shaft 30 may fall within a range of 120 to 260 degrees, specifically about 215 degrees.

In the second embodiment, an ejection hole 412 formed at the base end side of the filtering portion 43 is located closest to the exhaust port 5 when viewed in the rotational direction. A straight line connecting the ejection hole 412 and the center O1 of the rotary shaft 30 is indicated as L0. A length of the straight line L0 is about 640 mm, and a length of the straight line L1a is about 360 mm. In addition, an angle θ1 between the straight line L1a and the straight line L0 may be 140 degrees.

As described above, even in the case where the exhaust port 5 is formed in the bottom surface 202 of the housing 2, the positional relationship between the gas supply port 41 and the exhaust port 5 is set as in the first embodiment. With this configuration, it is possible to sufficiently spread the purge gas throughout the interior of the housing 2, thus suppressing the staying of oxygen and reducing the oxygen concentration.

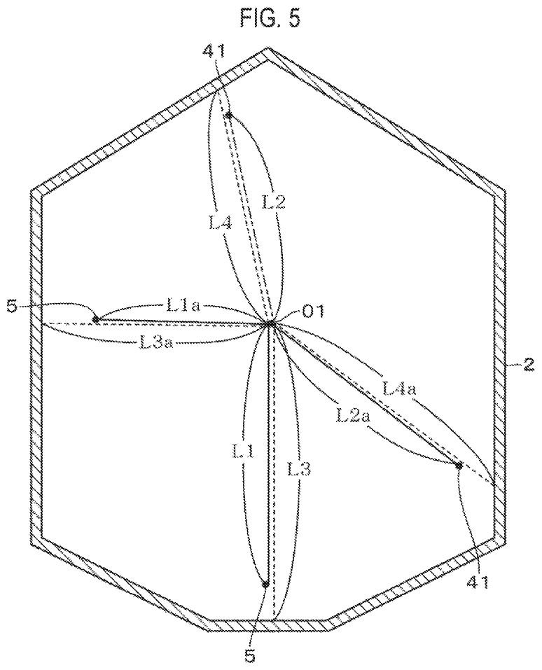

It has been confirmed that the effect of reducing the oxygen concentration inside the housing 2 as described above is obtained in the layout of the gas supply port 41 and the exhaust port 5 in the first and second embodiments. The layout of the gas supply port 41 and the exhaust port 5 in each of these embodiments will be described in more detail with reference to a schematic view illustrated in FIG. 5. In order to keep the oxygen concentration at a low level, it is preferable to set the distance between the gas supply port 41 and the exhaust port 5 inside the housing 2 to a relatively long level as described above.

In FIG. 5, the straight line L1 (L1a) extending from the center O1 of the rotary shaft 30 of the transfer mechanism 3 to the exhaust port 5 further extends toward the sidewall 201 of the housing 2. A straight line extending from the center O1 to the sidewall 201 formed by further extending the straight line L1 (Lila) in this manner is assumed to be L3 (L3a). In FIG. 5, for the sake of easier understanding of each line, the straight line L1 (L1a) and the straight line L3 (L3a) are illustrated to be offset from each other. The straight line L2 (L2a) extending from the center O1 of the rotary shaft 30 to the gas supply port 41 further extend toward the sidewall 201 of the housing 2. A straight line extending from the center O1 to the sidewall 201 formed by further extending the straight line L2 (L2a) in this manner is assumed to be L4 (L4a). Similarly, the straight line L4 (L4a) is illustrated to be slightly offset from the respective straight line L2 (L2a). The layout of the first embodiment is indicated by the straight lines L1, L2, L3, and L4, and the layout of the second embodiment is indicated by the straight lines L1a, L2a, L3a, and L4a.

In the first embodiment, the length of the straight line L1 is about 700 mm, and the exhaust port 5 is provided in the sidewall 201. Thus, a ratio of the straight line L1 to the straight line L3 in length is 1. In the first embodiment, the length of the straight line L2 is about 500 mm. Even if the length L2 is slightly smaller than 500 mm, it is considered that the gas is capable of being sufficiently spread throughout the interior of the housing 2. Thus, the length of the straight line L2 may be 400 mm or more. In the first embodiment, a ratio of the straight line L2 to the straight line L4 in length is about 0.8. it is considered that, even if the ratio of the straight line L2 to the straight line IA in length is slightly smaller than 0.8, the same effect can be obtained. Thus, the ratio of the straight line L2 to the straight line L4 in length may be 0.7 or more.

In the second embodiment, a length of the straight line L1a is about 360 mm. It is considered that, even if the length of the straight line L1a is slightly smaller than 360 mm, the gas is capable of being sufficiently spread throughout the interior of the housing 2. Thus, the length of the straight line L1a may be 300 mm or more. In the second embodiment, a ratio of the straight line L1a to the straight line L3a in length is about 0.8. It is considered that, even if the ratio of the straight line L1a to the straight line L3a in length is slightly smaller than 0.8, the same effect can be obtained. Thus, the ratio of the straight line L1a to the straight line L3a in length may be 0.7 or more.

In the second embodiment, a length of the straight line L2a is about 640 mm. It is considered that, even if the length of the straight line L2a is slightly smaller than 640 mm, the gas is capable of being sufficiently spread throughout the interior of the housing 2. Thus, the length of the straight line L2a may be 600 mm or more. In the second embodiment, a ratio of the straight line L2a to the straight line L4a in length is closer to 1 compared with that in the first embodiment. Thus, in consideration of the layouts of the first embodiment and the second embodiment, the lengths of the straight lines L1 and L1a may be 300 mm or more, and the lengths of the straight lines L2 and L2a may be 400 mm or more.

A ratio of the straight line L1 to the straight line L2 (ratio of the straight line L1a to the straight line L2a) in length is about 1 in the first embodiment, and about 0.6 in the second embodiment. When the values of the straight line L1 (L1a) and the straight line L2 (L2a) are set as large as possible in the internal space of the housing 2, the ratio of the straight line L1 to the straight line L2 (the ratio of the straight line L1a to the straight line L2a) in length becomes a value close to 1. In this case, in the second embodiment, the above-described effect of reducing the oxygen concentration is obtained even at a value relatively greatly deviated from 1. That is to say, it is estimated that it is possible to obtain the same effect as long as the ratio of the straight line L1 to the straight line L2 (the ratio of the straight line L1a to the straight line 12a) in length is close to 0.6, which is the value in the second embodiment. Accordingly, it is considered that the ratio of the straight line L1 to the straight line L2 (the ratio of the straight line L1a to the straight line L2a) in length may be 0.5 to 1. In addition, even if the gas supply part 4 is provided at the position where the exhaust port 5 is provided and the exhaust port 5 is provided at the position where the gas supply part 4 is provided in the second embodiment, it is considered that the distribution state of the gas inside the housing 2 does not greatly change. Therefore, it is considered that the ratio of the straight line L1 to the straight line L2 (the ratio of the straight line L1a to the straight line L2a) in length may be 0.5 to 15.

As described above, in the vacuum transfer module 11 according to the present disclosure, the gas supply port 41 at the tip end of the gas supply path 42 may be located at a position where the angle θ between the first straight line and the second straight line falls within a range of 100 to 260 degrees in a plan view. Therefore, even if the connection portion between the gas supply path 42 and the housing 2 falls outside the range of the angle θ in a plan view, the gas supply path 42 may be disposed inside the housing 2 and the gas supply port 41 of at the tip end thereof may be disposed at a position within the range of the angle θ. In addition, the gas supply part 4 has a configuration in which the gas supply port 41 is opened inside the housing 2. Thus, the gas supply port 41 may be configured to be opened in the sidewall 201, the bottom surface 202, or the ceiling surface of the housing 2 instead of extending the gas supply path 42 inside the housing 2. Furthermore, it is not necessarily required to provide the filtering portion 43. For example, the gas supply port 41 may be covered with a sheet-type porous body. Alternatively, a filtering member made of a porous body may be provided inside the gas supply path 42 or outside the housing 2.

In some embodiments, a plurality of exhaust ports may be provided. In the case where the plurality of exhaust ports are provided, the exhaust port located farthest from the gas supply port in the rotational direction of the rotary shaft corresponds to an exhaust port cited in the accompanying claims. The housing is not limited to have the illustrated heptagonal shape in a plan view. In some embodiments, the housing may have a hexagonal shape or a quadrilateral shape in a plan view. The rotary shaft of the transfer mechanism may not be provided in the central portion of the housing, but may be provided at a position near either the front, rear, left, or right. The rotary shaft of the transfer mechanism is provided at a fixed position inside the housing, but is not limited thereto. In some embodiments, the rotary shaft of the transfer mechanism may be configured to move upward and downward in the vertical direction as long as a horizontal position of the rotary shaft (in a lateral direction is fixed.

### EXAMPLES

In the apparatus of the first embodiment shown in FIG. 1, the nitrogen gas was supplied from the ejection holes 411 of the filtering portion 43 through the gas supply port 41 such that the interior of the housing 2 has a specific pressure measurement, and simultaneously, the purge gas was exhausted through the exhaust port 5. The concentration of oxygen inside the housing 2 was measured (Example 1). The measurement of the oxygen concentration was performed using a sensor 200 for detecting the oxygen concentration, which is provided between the load-lock module 232 and the base 31 inside the housing 2 as indicated by a dotted line in FIG. 2. The similar measurement also performed in a vacuum processing apparatus provided with the conventional vacuum transfer module illustrated in FIG. 6 (Comparative Example 1). The gas supply part 4 in the conventional apparatus was located at a position at which the angle θ between the first straight line L1b connecting the exhaust port 5 and the rotary shaft 30 and the second straight line L2b connecting the gas supply port 41 and the rotary shaft 30 is about 50 degrees.

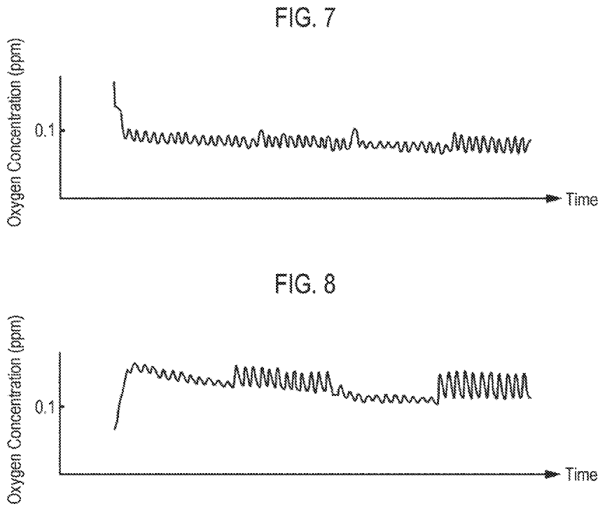

The measurement result of Example 1 is represented in FIG. 7, and the measurement result of Comparative Example 1 is represented in FIG. 8. In each of FIGS. 7 and 8, the vertical axis represents the oxygen concentration, and the horizontal axis represents time. From these results, it was confirmed that the oxygen concentration in Example 1 is lower than that in Comparative Example 1, and that the average oxygen concentration in Example 1 is 0.08 ppm and the average oxygen concentration in Comparative Example 1 is 0.12 ppm. In FIGS. 7 and 8, there are a time zone where the oxygen concentration is relatively high and a time zone where the oxygen concentration is relatively low. This is because the measurements were performed while changing the pressure conditions of the load-lock module and the processing module. In Example 1 and Comparative Example 1, the measurements were performed while keeping the pressure conditions constant.

Moreover, the similar measurement was performed in the vacuum processing apparatus 1 provided with the vacuum transfer module 11 of the second embodiment illustrated in FIG. 4 (Example 2). As a result, it was confirmed that the average oxygen concentration inside the housing 2 is 0.02 ppm.

The angle θ between the first straight line and the second straight line in Example 1 was about 190 degrees, the angle θ in Example 2 was about 215 degrees, and the angle θ in Comparative Example 1 was about 50 degrees. Accordingly, it was confirmed from the above measurement results that the oxygen concentration side the housing 2 changes depending on the formation locations of the gas supply port 41 and the exhaust port 5. As described in the above embodiments, it was confirmed that the oxygen concentration inside the housing 2 is decreased when the angle θ that represents the positional relationship between the gas supply port 41 and the exhaust port 5 is relatively large. It is considered that the oxygen concentration changes depending on the change in the angle θ because the distribution of the purge gas inside the housing 2 changes as described above.

From the measurement results, it was considered effective to arrange the gas supply port 41 and the exhaust port 5 so as to be greatly separated from each other as described above. Thus, it was considered effective to set the angle θ to a value close to 180 degrees when viewed from the rotary shaft 30 provided inside the housing 20. The position indicated by the angle θ in Example 2 is substantially the same as the position indicated by the angle θ1 in FIG. 4. From this, it was considered that the angle θ in Example 2 may be regarded as about 140 degrees. It was considered that the oxygen concentration does not change greatly even if the angle θ is slightly smaller than 140 degrees.

In addition, from the viewpoint of a practical use, the oxygen concentration inside the housing 2 may be 0.1 ppm or lower. The oxygen concentration was about 0.02 ppm when the angle θ in Example is about 140 degrees. The oxygen concentration was 0.12 ppm when the angle θ in Comparative Example 1 was about 50 degrees. Assuming that the oxygen concentration changes depending on the angle θ, it is considered that the oxygen concentration becomes about 0.1 ppm at 100 degrees, which is approximately halfway between 50 degrees and 140 degrees. Accordingly, it is considered effective if the angle θ falls within a range of 100 to 180 degrees. The arrangement in which the angle θ falls within the range of 100 to 180 degrees is symmetrical to the arrangement in which the angle θ falls within the range of 180 to 260 degrees. Therefore, it is effective to set the angle θ in the range of 100 to 260 degrees.

Furthermore, in the vacuum processing apparatus according to Example 1, TiN films were sequentially formed on the plurality of wafers W in the respective processing modules 21. The sheet resistance value (Rs resistance value) of the TiN film formed on each wafer W was measured. Each TiN film was formed by the method described above. The nitrogen gas was supplied into the housing 2 from the ejection holes 411 of the filtering portion 43 through the gas supply port 41. The nitrogen gas was exhausted from the exhaust port 5 so that the internal pressure of the housing 2 was adjusted to a predetermined pressure (Example 3). The similar measurement was also performed in the conventional vacuum processing apparatus provided with the conventional vacuum transfer module illustrated in FIG. 6 (Comparative Example 2).

As a result, compared with the sheet resistance value in Comparative Example 2, the average value of the sheet resistance value in Example 3 was improved by about 4.5%. In the vacuum processing apparatus illustrated in FIG. 1, it is estimated that, since the oxygen concentration inside the housing 2 was lowered, the TiN film is hardly oxidized when the wafer W is being transferred through the interior of the housing 2, which suppressing an increase in sheet resistance value. That is to say, the sheet resistance value depends on the oxygen concentration inside the housing 2. Thus, it is understood that, when the oxygen concentration inside the housing 2 is low, the increase in sheet resistance value is suppressed, which suppresses a deterioration in film quality.

In the forgoing, the vacuum transfer module of the present disclosure is not limited to the above embodiments. The shape and formation location of the gas supply port, and the shape and formation location of the exhaust port are not limited to the configurations described above as long as the angle between the first straight line connecting the exhaust port and the rotary shaft and the second straight line connecting the gas supply port and the rotary shaft falls within the range of 100 to 260 degrees. In addition, the vacuum transfer module of the present disclosure is an example, and the layouts and shapes of the housing, the load-lock module, and the processing module are appropriately changeable.

According to the present disclosure, it is possible to reduce the oxygen concentration of a vacuum transfer module.

It should be noted that the embodiments disclosed herein are exemplary in all respects and are not restrictive. The above-described embodiments may be omitted, replaced or modified in various forms without departing from the scope and spirit of the appended claims.

What is claimed is:

1. A vacuum transfer module comprising:
a housing whose interior is kept in a vacuum atmosphere, and to which a load-lock module and a processing module configured to perform a vacuum process on a workpiece are connected laterally from an outside of the housing;
a transfer mechanism including a rotation body configured to rotate around a rotary shaft provided at a fixed position inside the housing, the transfer mechanism configured to transfer the workpiece between the load-lock module and the processing module through the interior of the housing kept in the vacuum atmosphere;
a gas supply port opened inside the housing to supply an inert gas for purging the interior of the housing; and
an exhaust port opened inside the housing and through which the interior of the housing is exhausted to form the vacuum atmosphere when the inert gas is supplied from the gas supply port, the exhaust port being formed such that an angle between a first straight line connecting the exhaust port and the rotary shaft, and a second straight line connecting the gas supply port and the rotary shaft falls within a range of 100 to 260 degrees in a plan view.

2. The vacuum transfer module of claim 1, wherein the gas supply port and the exhaust port are provided below a transfer path through which the workpiece is transferred by the transfer mechanism inside the housing.

3. The vacuum transfer module of claim 1, wherein a first length from the rotary shaft to the exhaust port in the first straight line is 300 mm or more.

4. The vacuum transfer module of claim 1, wherein a second length from the rotary shaft to the gas supply port in the second straight line is 400 mm or more.

5. The vacuum transfer module of claim 1, wherein a ratio of the first length to the second length falls within a range of 0.5 to 1.5.

6. The vacuum transfer module of claim 1, wherein an oxygen concentration inside the housing when the workpiece is being transferred into the housing falls within a range of 0.1 ppm or lower.

7. A vacuum transfer method comprising:
rotating a rotation body around a rotary shaft provided at a fixed position inside a housing, wherein an interior of the housing is kept in a vacuum atmosphere, and a load-lock module and a processing module configured to perform a vacuum process on a workpiece are connected to the housing laterally from an outside of the housing;
transferring the workpiece between the load-lock module and the processing module through the interior of the housing kept in the vacuum atmosphere by a transfer mechanism including the rotation body;
supplying an inert gas into the housing to purge the interior of the housing from a gas supply port opened inside the housing; and
exhausting the interior of the housing from an exhaust port to form the vacuum atmosphere when the inert gas is supplied from the gas supply port, the exhaust port being formed such that an angle between a first straight line connecting the exhaust port and the rotary shaft, and a second straight line connecting the gas supply port and the rotary shaft falls within a range of 100 to 260 degrees in a plan view.
